(19) United States
(12) Patent Application Publication
(10) Pub. No.: US 2013/0095626 A1
(43) Pub. Date: Apr. 18, 2013

(54) METHOD FOR MANUFACTURING SEMICONDUCTOR DEVICE

(71) Applicant: Toshiyuki SASAKI, Kanagawa-ken (JP)

(72) Inventor: Toshiyuki SASAKI, Kanagawa-ken (JP)

(21) Appl. No.: 13/424,822

(22) Filed: Mar. 20, 2012

(30) Foreign Application Priority Data
Oct. 18, 2011 (JP) 2011-228834

(51) Int. Cl. H01L 21/336; H01L 21/28

(52) U.S. Cl. 438/270; 438/585; 257/E21.41; 257/E21.158

(57) ABSTRACT

According to one embodiment, a method for manufacturing a semiconductor device, includes: and forming, on an upper face of a silicon substrate, a plurality of concave portions extending in a first direction, performing, in a gas that contains fluorine or a fluoride, plasma processing on the silicon substrate in which the concave portions are formed. The method further includes performing, in a gas that contains hydrogen, thermal processing on the silicon substrate after completion of performing the plasma processing; forming an insulating film on an inner face of the concave portions after completion of performing the thermal processing; and forming a conductive film on the insulating film.

### CROSS-REFERENCE TO RELATED APPLICATIONS

This application is based upon and claims the benefit of priority from the prior Japanese Patent Application No. 2011-228834, filed on Oct. 18, 2011; the entire contents of which are incorporated herein by reference.

### FIELD

Embodiments described herein relate generally to a method for manufacturing semiconductor device.

### BACKGROUND

In the transistor (hereinafter also referred to a “RCAT” (recessed channel transistor)) of a recess structure, a part of a gate electrode is embedded inside a groove formed in a semiconductor substrate. In the RCAT, an insulating film formed on the inner face of the groove serves as a gate insulating film, and a region along the groove in the semiconductor substrate constitutes a channel. Although the groove in which the part of the gate electrode is embedded is formed by performing reactive on etching (RIE) on the semiconductor substrate, when variations in the shape of the groove are generated, the electrical characteristics of the RCAT are reduced.

### BRIEF DESCRIPTION OF THE DRAWINGS

FIGS. 1A to 1C are process cross-sectional views illustrating a method for manufacturing a semiconductor device according to a first embodiment;

FIGS. 2A to 2C are process cross-sectional views illustrating the method for manufacturing the semiconductor device according to the first embodiment;

FIG. 3A is a process cross-sectional view illustrating the method for manufacturing a semiconductor device according to the first embodiment, and FIG. 3B is a process plan view illustrating the method for manufacturing a semiconductor device according to the first embodiment;

FIG. 4A is a process cross-sectional view illustrating the method for manufacturing a semiconductor device according to the first embodiment, and FIG. 4B is a process plan view illustrating the method for manufacturing a semiconductor device according to the first embodiment;

FIGS. 5A to 5C are process cross-sectional views illustrating the method for manufacturing the semiconductor device according to the first embodiment, wherein FIG. 5A is a cross-sectional view taken along line A-A′ shown in FIG. 4B, FIG. 5B is a cross-sectional view taken along line B-B′ shown in FIG. 4B, and FIG. 5C is a cross-sectional view taken along line C-C′ shown in FIG. 4B;

FIGS. 6A to 6C are process cross-sectional views illustrating the method for manufacturing the semiconductor device according to the first embodiment, wherein FIG. 6A is a cross-sectional view taken along line A-A′ shown in FIGS. 6B and 6C, FIG. 6B is a cross-sectional view taken along line B-B′ shown in FIG. 6A, and FIG. 6C is a cross-sectional view taken along line C-C′ shown in FIG. 6A:

FIGS. 7A and 7B are process cross-sectional views illustrating the method for manufacturing the semiconductor device according to the first embodiment, wherein FIG. 7A is a cross-sectional view taken along line A-A′ shown in FIG. 7B, and FIG. 7B is a cross-sectional view taken along line B-B′ shown in FIG. 7A;

FIGS. 8A and 8B are process cross-sectional views illustrating the method for manufacturing the semiconductor device according to the first embodiment, wherein FIG. 8A is a cross-sectional view taken along line A-A′ shown in FIG. 8B, and FIG. 8B is a cross-sectional view taken along line B-B′ shown in FIG. 8A;

FIGS. 9A and 9B are process cross-sectional views illustrating the method for manufacturing the semiconductor device according to the first embodiment, wherein FIG. 9A is a cross-sectional view taken along line A-A′ shown in FIG. 9B, and FIG. 9B is a cross-sectional view taken along line B-B′ shown in FIG. 9A;

FIGS. 10A and 10B are process cross-sectional views illustrating the method for manufacturing the semiconductor device according to the first embodiment, wherein FIG. 10A is a cross-sectional view taken along line A-A′ shown in FIG. 10B, and FIG. 10B is a cross-sectional view taken along line B-B′ shown in FIG. 10A;

FIGS. 11A and 11B are process cross-sectional views illustrating the method for manufacturing the semiconductor device according to the first embodiment;

FIGS. 12A and 12B are process cross-sectional views illustrating the method for manufacturing the semiconductor device according to the first embodiment;

FIGS. 13A and 13B are process cross-sectional views illustrating the method for manufacturing the semiconductor device according to the first embodiment;

FIG. 14 is a process cross-sectional view illustrating the method for manufacturing the semiconductor device according to the first embodiment;

FIG. 15 is a cross-sectional view illustrating grooves in the method for manufacturing the semiconductor device according to the first embodiment;

FIG. 16 is a cross-sectional view illustrating grooves in a method for manufacturing a semiconductor device according to a modification of the first embodiment;

FIGS. 17A and 17B are process cross-sectional views illustrating a method for manufacturing a semiconductor device according to the comparative example of the first embodiment, wherein FIG. 17A is a cross-sectional view taken along line A-A′ shown in FIG. 17B, and FIG. 17B is a cross-sectional view taken along line B-B′ shown in FIG. 17A;

FIG. 18 is a cross-sectional view illustrating grooves in the method for manufacturing the semiconductor device according to the comparative example of the first embodiment;

FIGS. 19A and 19B are process cross-sectional views illustrating a method for manufacturing a semiconductor device according to a second embodiment, wherein FIG. 19A is a cross-sectional view taken along line A-A′ shown in FIG. 19B, and FIG. 19B is a cross-sectional view taken along line B-B′ shown in FIG. 19A;

FIGS. 20A and 20B are process cross-sectional views illustrating the method for manufacturing the semiconductor device according to the second embodiment, wherein FIG. 20A is a cross-sectional view taken along line A-A′ shown in FIG. 20B, and FIG. 20B is a cross-sectional view taken along line B-B′ shown in FIG. 20A;

FIGS. 21A and 21B are process cross-sectional views illustrating the method for manufacturing the semiconductor device according to the second embodiment, wherein FIG. 21A is a cross-sectional view taken along line A-A′ shown in FIG. 21B, and FIG. 21B is a cross-sectional view taken along line B-B′ shown in FIG. 21A;

FIGS. 22A and 22B are process cross-sectional views illustrating a method for manufacturing a semiconductor device according to the third embodiment, and FIG. 22A is a cross-sectional view taken along line A-A′ shown in FIG. 22B, and FIG. 22B is a cross-sectional view taken along line B-B′ shown in FIG. 22A;

FIGS. 23A and 23B are process cross-sectional views illustrating the method for manufacturing the semiconductor device according to the third embodiment, wherein FIG. 23A is a cross-sectional view taken along line A-A′ shown in FIG. 23B, and FIG. 23B is a cross-sectional view taken along line B-B′ shown in FIG. 23A; and

FIGS. 24A and 24B are process cross-sectional views illustrating the method for manufacturing the semiconductor device according to the third embodiment, wherein FIG. 24A is a cross-sectional view taken along line A-A′ shown in FIG. 24B, and FIG. 24B is a cross-sectional view taken along line B-B′ shown in FIG. 24A.

### DETAILED DESCRIPTION

In general, according to one embodiment, a method for manufacturing a semiconductor device, includes: forming, on an upper face of a silicon substrate, a plurality of concave portions extending in a first direction, performing, in a gas that contains fluorine or a fluoride, plasma processing on the silicon substrate in which the concave portions are formed; performing, in a gas that contains hydrogen, thermal processing on the silicon substrate after completion of performing the plasma processing; forming an insulating film on an inner face of the concave portions after completion of performing the thermal processing; and forming a conductive film on the insulating film.

In general, according to another embodiment, a method for manufacturing a semiconductor device, includes: forming, on an upper layer of a silicon substrate, a plurality of columnar bodies extending in a first direction; performing, in a gas that contains fluorine or a fluoride, plasma processing on the silicon substrate in which the columnar bodies are formed; performing, in a gas that contains hydrogen, thermal processing on the silicon substrate after completion of performing the plasma processing; forming an insulating film on an upper face and a side face of the columnar bodies after completion of performing the thermal processing; and forming a conductive film on the insulating film.

### First Embodiment

Embodiments of the invention will be described below with reference to the drawings.

First, the first embodiment will be described.

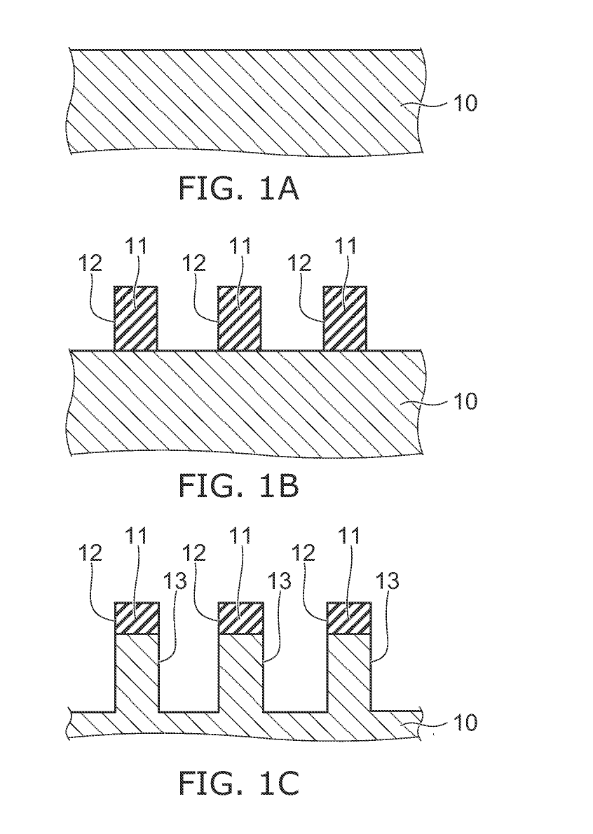

FIGS. 1A to 1C, 2A to 2C, 3A and 3B and 4A and 4B are process cross-sectional views illustrating a method for manufacturing a semiconductor device according to the first embodiment.

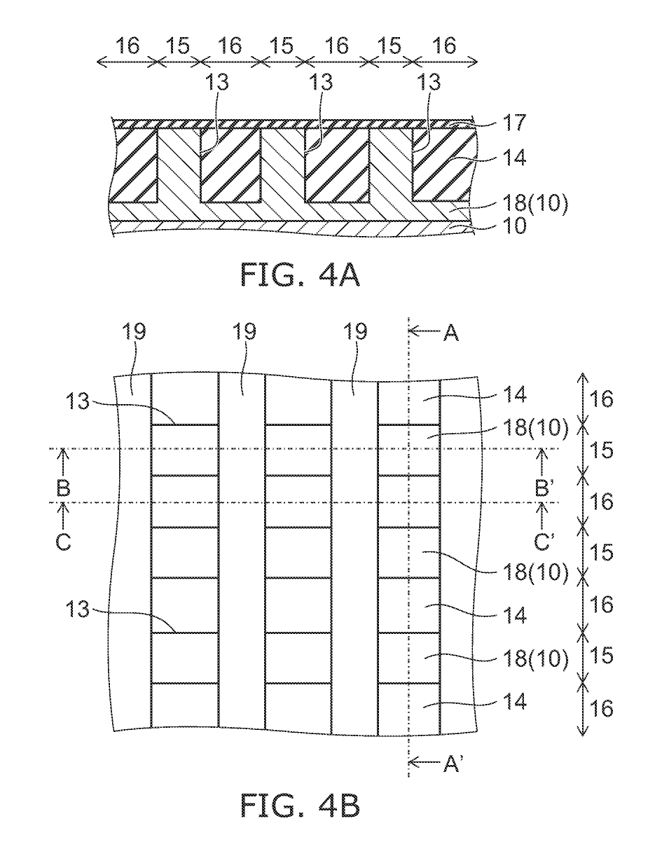

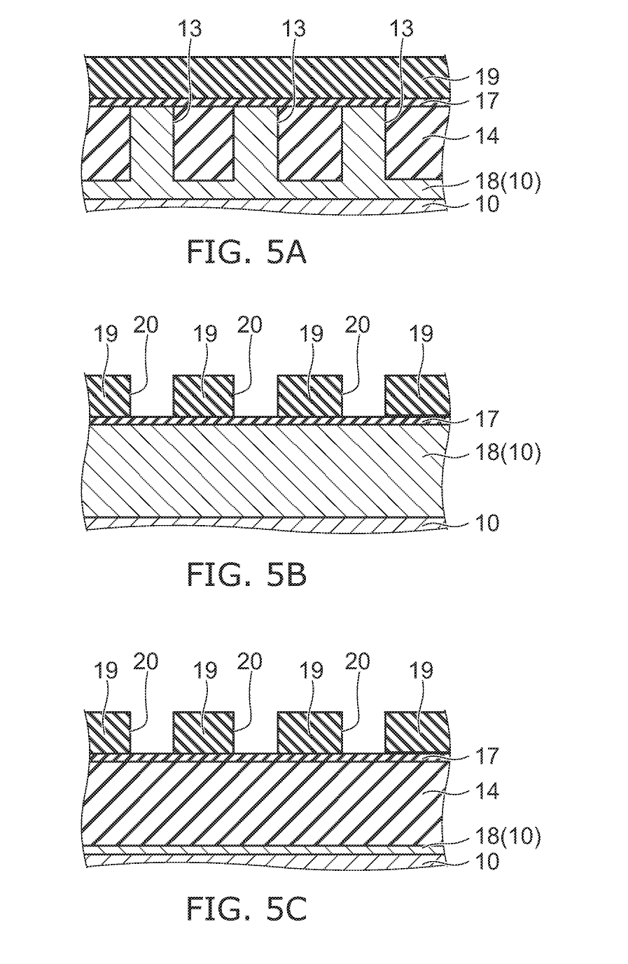

FIGS. 5A to 5C are process cross-sectional views illustrating the method for manufacturing the semiconductor device according to the first embodiment, FIG. 5A is a cross-sectional view taken along line A-A′ shown in FIG. 4B, FIG. 5B is a cross-sectional view taken along line B-B′ shown in FIG. 4B, and FIG. 5C is a cross-sectional view taken along line C-C′ shown in FIG. 4B.

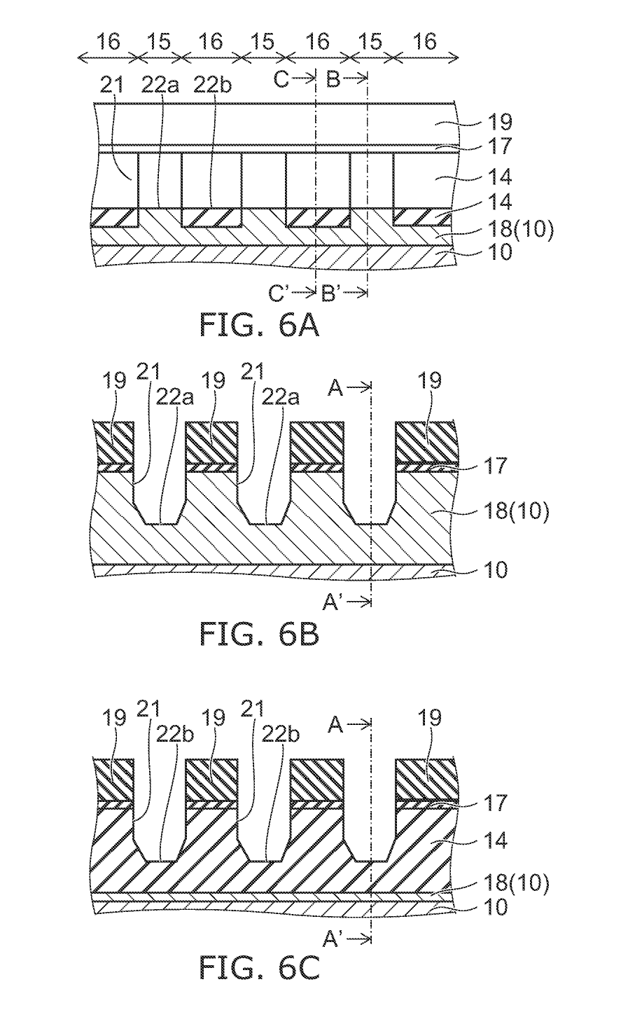

FIGS. 6A to 6C are process cross-sectional views illustrating the method for manufacturing the semiconductor device according to the first embodiment, FIG. 6A is a cross-sectional view taken along line A-A′ shown in FIGS. 6B and 6C, FIG. 6B is a cross-sectional view taken along line B-B′ shown in FIG. 6A, and FIG. 6C is a cross-sectional view taken along line C-C′ shown in FIG. 6A.

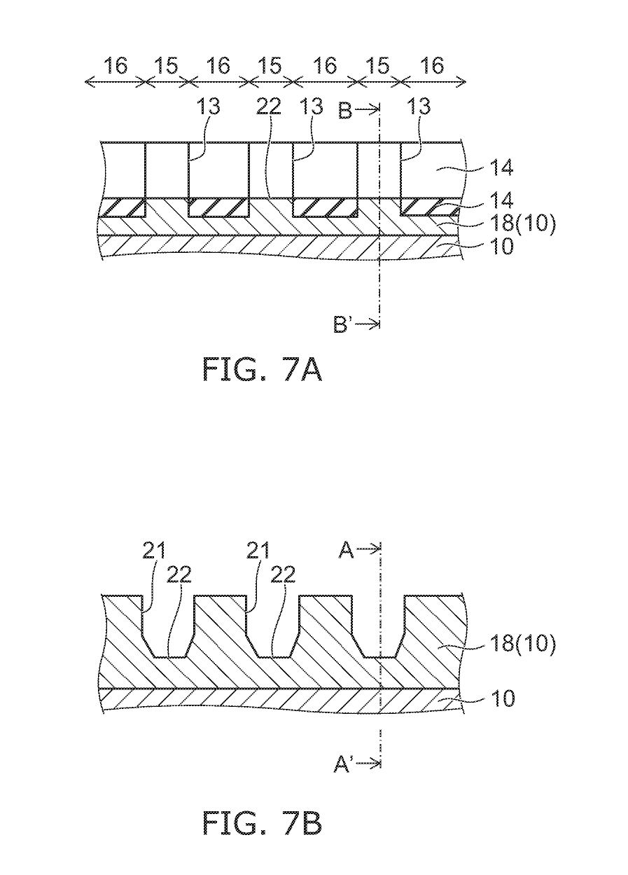

FIGS. 7A and 7B are process cross-sectional views illustrating the method for manufacturing the semiconductor device according to the first embodiment, FIG. 7A is a cross-sectional view taken along line A-A′ shown in FIG. 7B, and FIG. 7B is a cross-sectional view taken along line B-B′ shown in FIG. 7A.

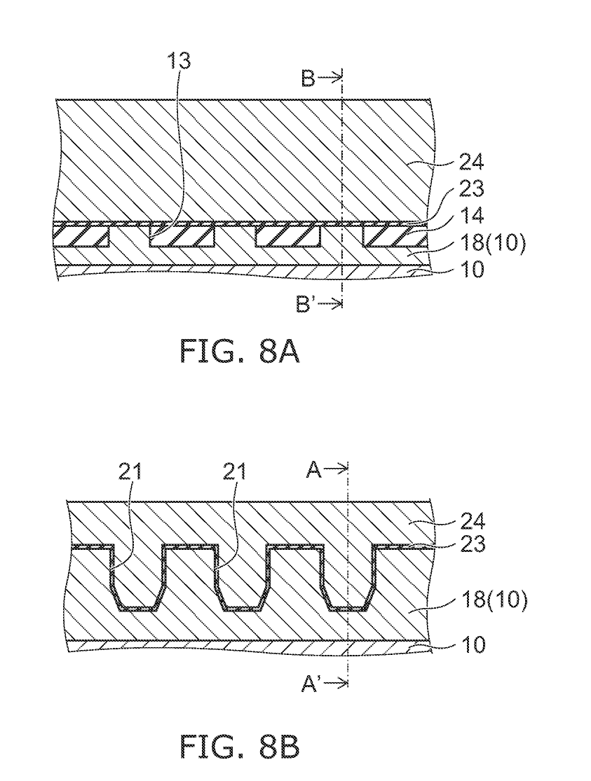

FIGS. 8A and 8B are process cross-sectional views illustrating the method for manufacturing the semiconductor device according to the first embodiment, FIG. 8A is a cross-sectional view taken along line A-A′ shown in FIG. 8B, and FIG. 8B is a cross-sectional view taken along line B-B′ shown in FIG. 8A.

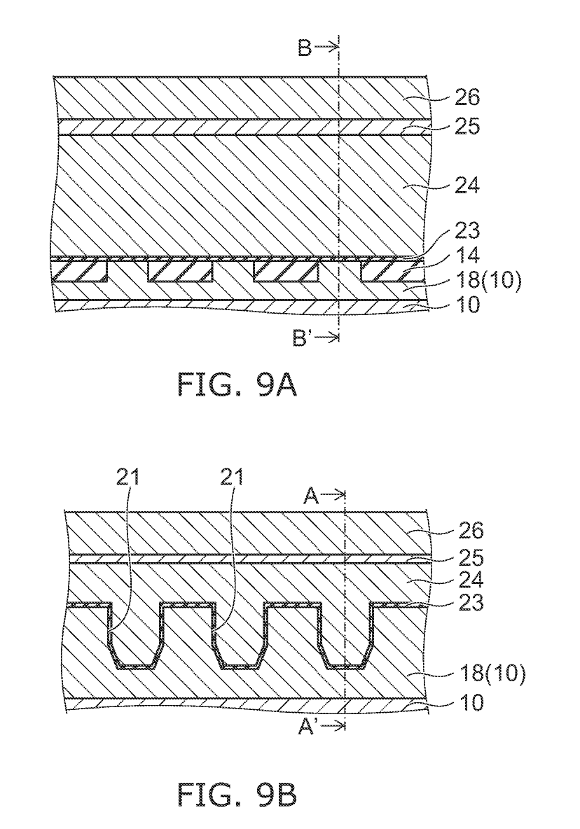

FIGS. 9A and 9B are process cross-sectional views illustrating the method for manufacturing the semiconductor device according to the first embodiment, FIG. 9A is a cross-sectional view taken along line A-A′ shown in FIG. 9B, and FIG. 9B is a cross-sectional view taken along line B-B′ shown in FIG. 9A.

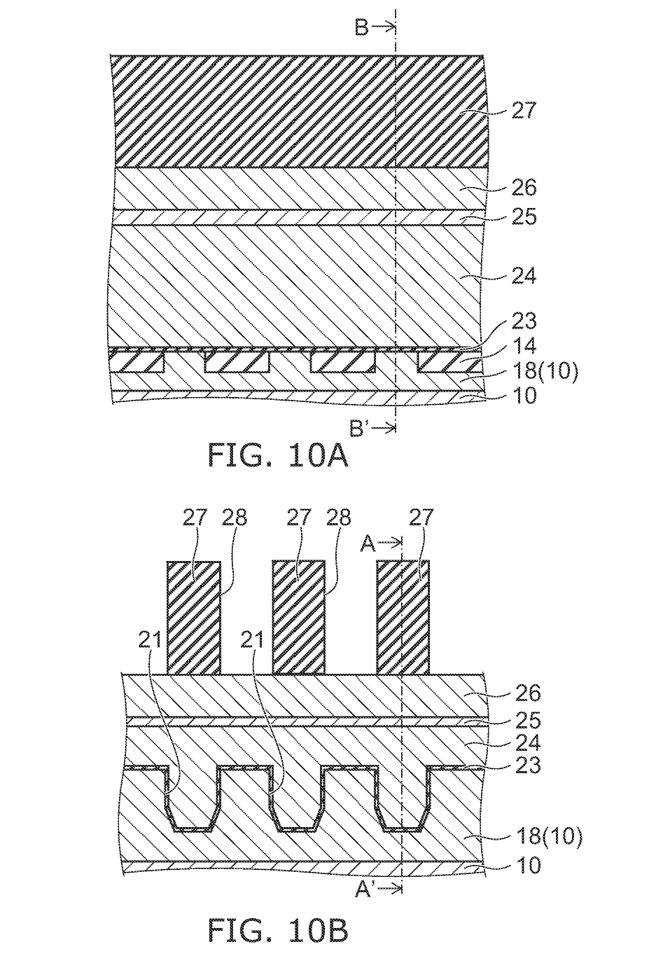

FIGS. 10A and 10B are process cross-sectional views illustrating the method for manufacturing the semiconductor device according to the first embodiment, FIG. 10A is a cross-sectional view taken along line A-A′ shown in FIG. 10B, and FIG. 10B is a cross-sectional view taken along line B-B′ shown in FIG. 10A.

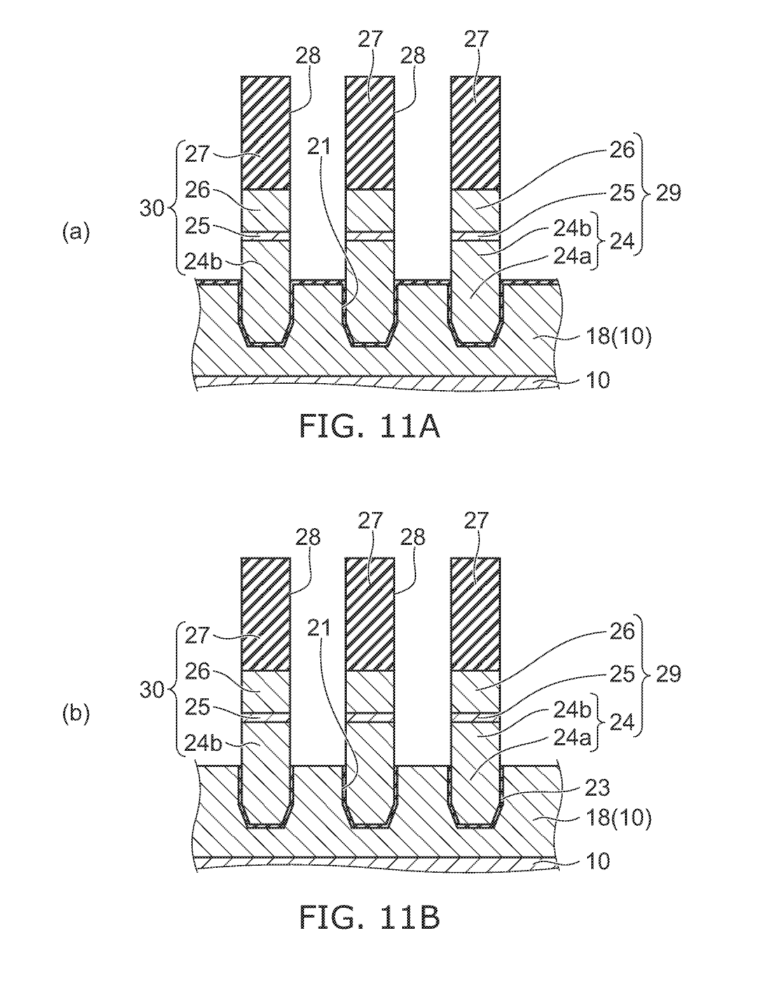

FIGS. 11A and 11B are process cross-sectional views illustrating the method for manufacturing the semiconductor device according to the first embodiment.

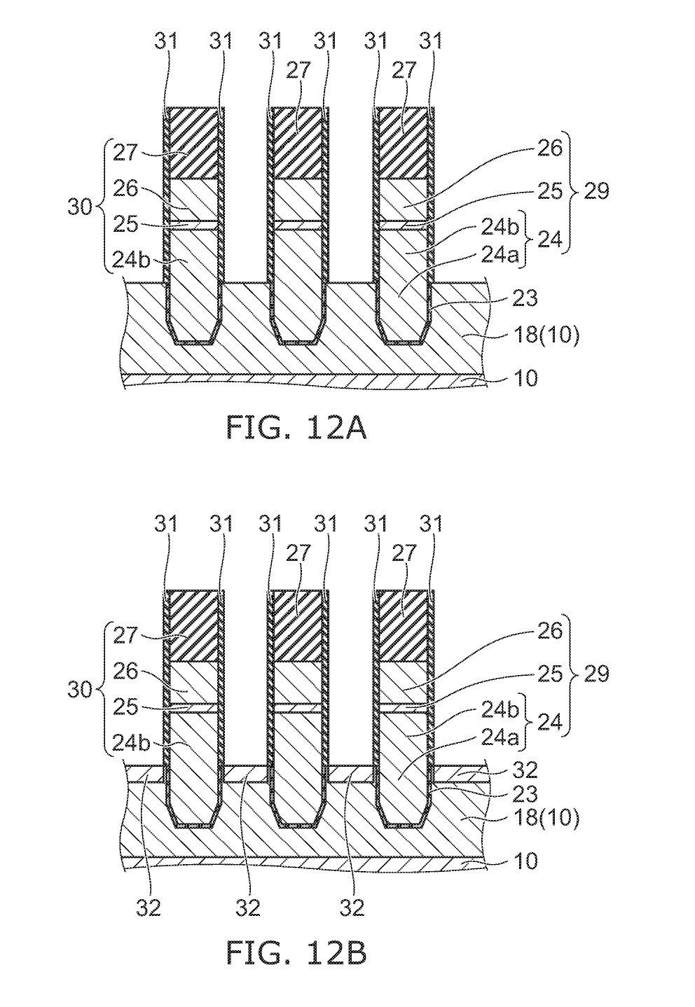

FIGS. 12A and 12B are process cross-sectional views illustrating the method for manufacturing the semiconductor device according to the first embodiment.

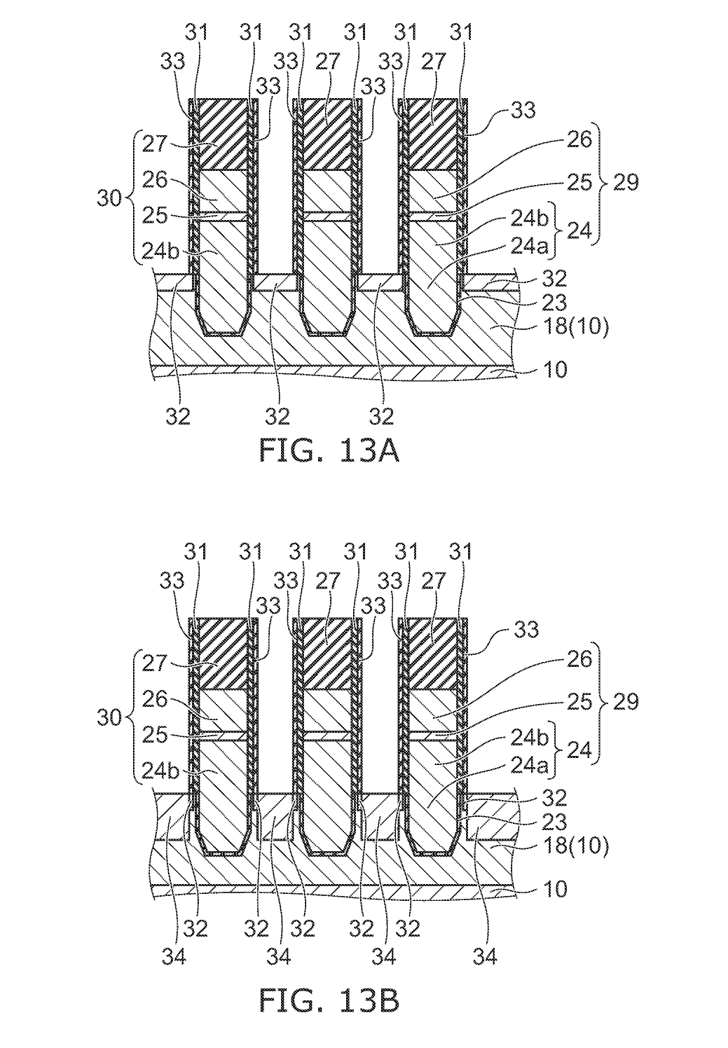

FIGS. 13A and 13B are process cross-sectional views illustrating the method for manufacturing the semiconductor device according to the first embodiment.

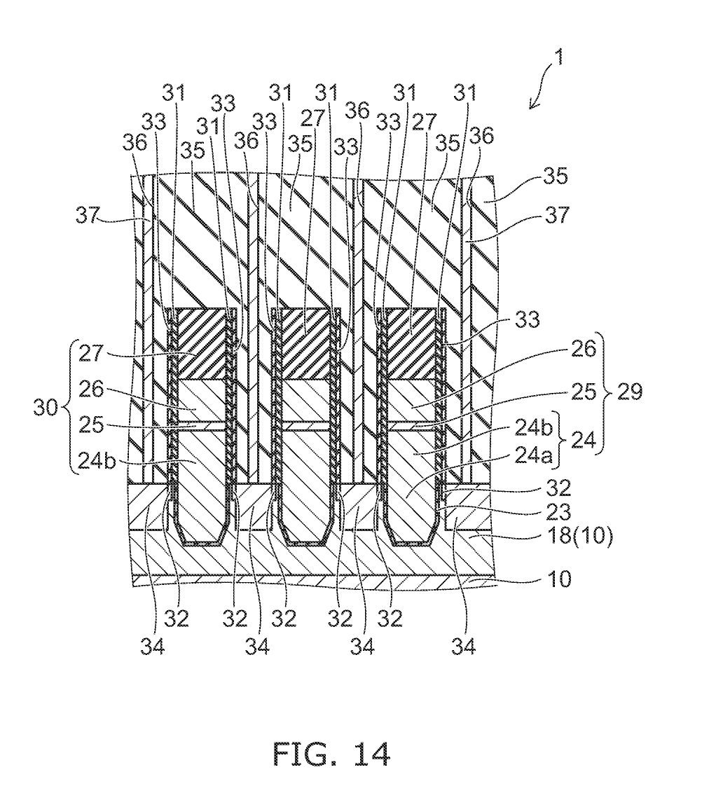

FIG. 14 is a process cross-sectional view illustrating the method for manufacturing the semiconductor device according to the first embodiment.

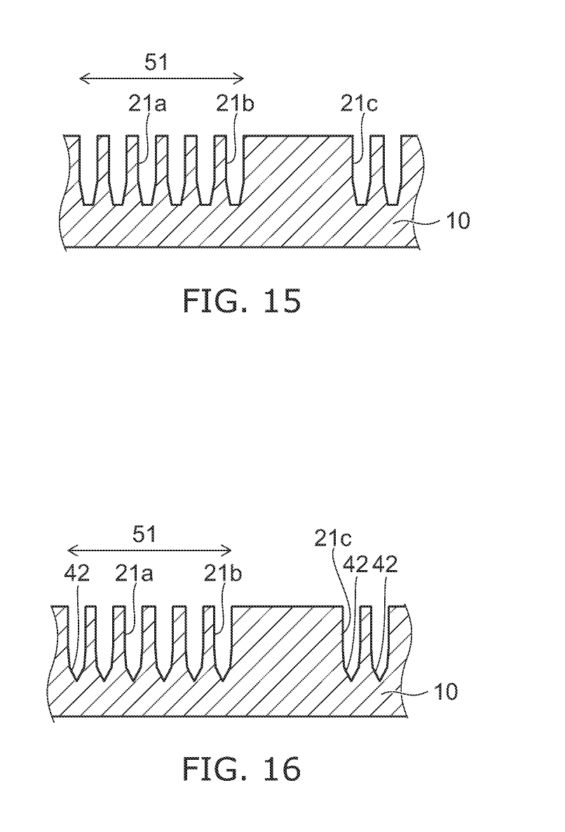

FIG. 15 is a cross-sectional view illustrating grooves in the method for manufacturing the semiconductor device according to the first embodiment.

First, as shown in FIG. 1A, for example, a silicon substrate 10 formed of single crystal silicon (Si) is prepared.

Then, as shown in FIG. 1B, on the silicon substrate 10, for example, a silicon nitride film (SiN film) is formed as a film serving as a hard mask 11, and after that the hard mask 11 is formed by performing patterning through the use of a photolithography method. In the hard mask 11, a plurality of openings 12 which extend in one direction parallel to the upper face of the silicon substrate 10 and which are aligned in a direction perpendicular to the one direction are formed.

After that, as shown in FIG. 1C, RIE is performed by using the hard mask 11 as a mask, and thus a groove 13 is formed in an upper layer portion of the silicon substrate 10.

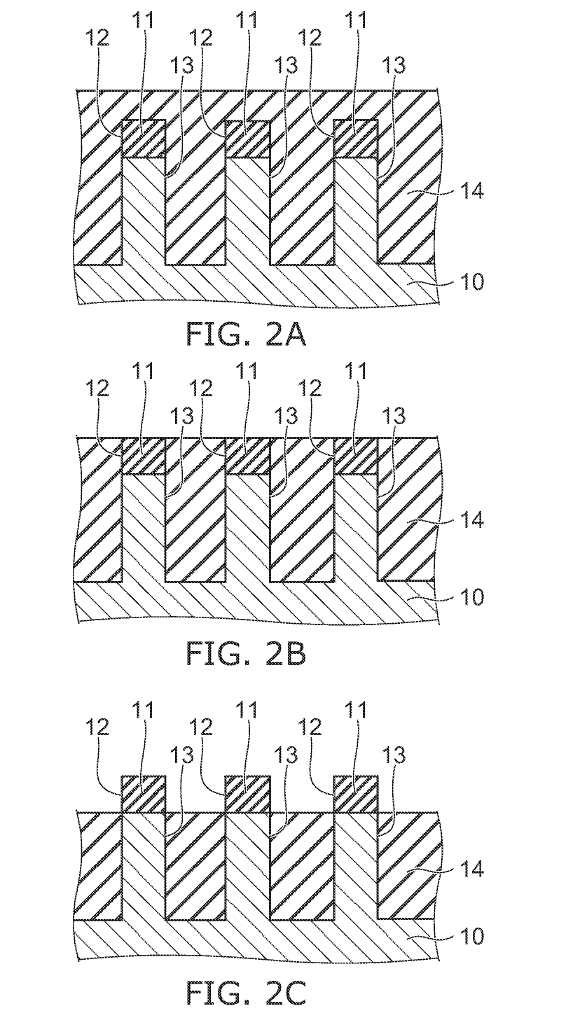

Next, as shown in FIG. 2A, a silicon oxide is deposited on the silicon substrate 10. Because of this, the inside of the groove 13 is embedded, and a silicon oxide film 14 is formed so as to cover the hard mask 11.

Then, as shown in FIG. 2B, the silicon oxide film 14 is polished by a chemical mechanical polishing (CMP) method until the surface of the hard mask 11 appears.

Next, as shown in FIG. 2C, wet etching is performed to remove an upper portion of the silicon oxide film 14. Because of this, the upper face of the silicon oxide film 14 is lowered back until the height thereof becomes equal to that of the lower face of the hard mask 11, that is, that of the upper face of a portion of the silicon substrate 10 covered by the hard mask 11. After that, wet etching is performed, and the hard mask 11 is removed.

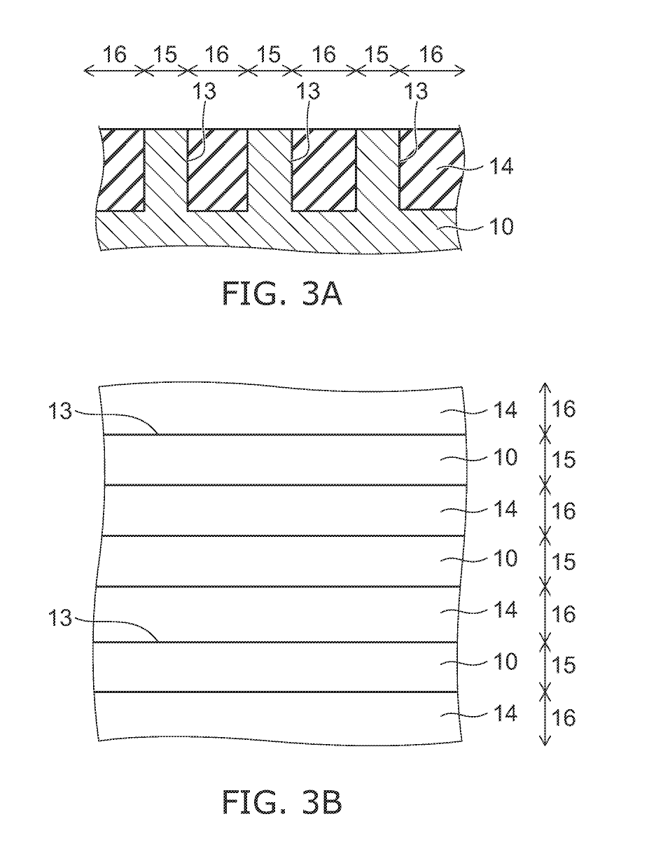

As shown in FIGS. 3A and 3B, a region in which the upper face of the silicon substrate 10 appears in the silicon substrate 10 at this stage as viewed from above is referred to as an “active region 15.” In addition, a region in which the upper face of the silicon oxide film 14 appears as viewed from above is referred to as an “STI region 16.” The active region 15 and the STI region 16 extend along one direction in the form of a stripe, and are alternately aligned.

Next, as shown in FIG. 4A, a silicon oxide film 17 is formed on the entire face. The silicon oxide film 17 covers both the upper face of the silicon substrate 10 in the active region 15 and the upper face of the silicon oxide film 14 in the STI region 16, After that, on implantation is performed from above the silicon oxide film 17, and thus, for example, boron is introduced as an impurity into the silicon substrate 10. The depth of the introduction ranges from the surface of the silicon substrate 10 to a position that is deeper than the bottom portion of the groove 13, Because of this, in the active region 15, boron is introduced in the range from the surface of the silicon substrate 10 to the position that is deeper than the bottom portion of the groove 13. In the STI region 16, boron is introduced in the range from the bottom face of the groove 13 to the position that is deeper than the bottom portion of the groove 13, A portion of the silicon substrate 10 into which boron is introduced serves as a p-type well 18.

Then, as shown in FIGS. 4B and 5A to 5C, on the silicon oxide film 17, for example, a silicon nitride film is formed as a film serving as a hard mask 19, and after that patterning is performed by a photolithography method or the like, thereby forming the hard mask 19. In the hard mask 19, a plurality of openings 20 are formed, which extend in a direction perpendicular to the groove 13 provided in order to form the STI region 16 within the surface of the silicon substrate 10 and which are aligned along the direction in which the groove 13 extends.

After that, as shown in FIGS. 6A to 6C, the silicon substrate 10 is mounted in a chamber (not shown), and RIE is performed using the hard mask 19 as a mask. Thus, the silicon oxide film 17 is selectively removed. Moreover, the silicon substrate 10 in the active region 15 and the silicon oxide film 14 in the STI region 16 are selectively removed. Here, when, for example, as the etching gas of RIE, CF₄ gas is used, it is possible to reduce a difference between the etching speed of the silicon and the etching speed of the silicon oxide. Therefore, it is possible to simultaneously process the silicon substrate 10 in the active region 15 and the silicon oxide film 14 in the STI region 16. In this way, a groove 21 is formed in the silicon substrate 10 in which the STI region 16 is formed.

As shown in FIG. 6A, a bottom face 22a of the groove 21 of the silicon substrate 10 in the active region 15 is formed in the shape of a flat face parallel to the upper face of the silicon substrate 10, and a bottom face 22b of the groove 21 of the silicon oxide film 14 in the STI region 16 is also formed in the shape of the flat face parallel to the upper face of the silicon substrate 10. The bottom face 22a and the bottom face 22b are formed to have the same depth. That is, the bottom face 22a and the bottom face 22b are connected without any step.

As shown in FIG. 6B, the grooves 21 are formed at regular intervals on the upper face of the silicon substrate 10. Each of the grooves 21 is formed so as to have the same shape. The side face of an upper portion of the groove 21 is formed perpendicular to the upper face of the silicon substrate 10. In addition, a lower portion of the groove 21 is formed to have an inclined face in which, as the groove extends deeper, it becomes thinner. Then, the bottom face 22a of the groove 21 is formed in the shape of the flat face parallel to the upper face of the silicon substrate 10.

When the groove 21 is formed by RIE, ions within an etching gas collide with the inner face of the groove 21. An impact at the time of the collision introduces defects in the silicon crystal in the inner face of the groove 21, and thereby forms a defect layer.

Moreover, when the groove 21 is formed by RIE, a deposition layer of a reaction product produced by RIE is formed on the inner face of the groove 21. When, for example, a CF-based etching gas is used, the deposition layer is a layer of a fluorocarbon-based deposition or a layer obtained by depositing a mixture of a silicon oxide and a halide.

In RIE described above, the defect layer and the deposition layer formed in the inner face of the groove 21 are hereinafter referred to as an “inhibition layer.”

When the groove 21 is formed, in the inner face of the groove 21, “roughness” is also produced in addition to the inhibition layer. The roughness is produced by the ions of the etching gas in RIE. The roughness can also be produced by etching using radicals. The roughness can further be produced by the deposition of an etching reaction product. The roughness includes the roughness related to an etching gas as described above and roughness produced by transfer of roughness on the surface of a resist formed on the hard mask 19 and roughness on the surface of the hard mask 19 to the inner face of the groove 21.

As shown in FIG. 6C, the grooves 21 are formed at regular intervals on the upper face of the silicon oxide film 14. Each of the grooves 21 is formed so as to have the same shape as the groove 21 shown in FIG. 6B. Therefore, a process cross-sectional view taken along line C-C′ shown in FIG. 6A will be hereinafter omitted. In FIGS. 7A and 7B to 10A and 10B, FIGS. 7A to 10A show a cross section corresponding to a cross section taken along line A-A′ of FIG. 4B, and FIGS. 7B to 10B show a cross section corresponding to a cross section taken along line B-B′ of FIG. 4B.

After that, the hard mask 19 is removed by heated phosphoric acid or the like. Furthermore, the silicon oxide film 17 that remains directly below the hard mask 19 is removed by diluted hydrofluoric add.

Then, as shown in FIGS. 7A and 7B, the silicon substrate 10 in which the grooves 21 are formed is plasma-processed in a gas that contains fluorine or a fluoride. Because of this, the inhibition layer formed in the inner face of the groove 21 is removed.

The gas that contains fluorine or a fluoride is a gas that contains at least a gas selected from a group consisting of, for example, a nitrogen trifluoride gas (NF₃), a fluorine gas (F₂) and sulphur hexafluoride (SF₆). Moreover, for example, the gas that contains fluorine or a fluoride can be a gas selected from a group consisting of a single gas of a nitrogen trifluoride gas (NF₃), a single gas of a fluorine gas (F₂) and a single gas of sulphur hexafluoride (SF₆).

The plasma processing is performed by introducing the gas described above into the chamber with the silicon substrate 10 being mounted in the chamber in which the RIE is performed and by applying a high-frequency voltage to the gas to put the gas in a plasma state. Here, a bias voltage is applied to the silicon substrate 10. The bias voltage Vdc is set to be not more than, for example, 100 V.

After the completion of the plasma processing, thermal processing is performed on the silicon substrate 10 in hydrogen (H₂) gas. The thermal processing temperature is set as, for example, 800° C. The thermal processing time is set as, for example, a few seconds. By this processing, silicon atoms in the inner face of the groove 21 are moved. The movement of the silicon atoms repairs the roughness on the inner face of the groove 21 caused by the RIE.

Next, as shown in FIGS. 8A and 8B, a gate insulating film 23, for example, a silicon oxide film is formed on the inner face of the groove 21 and the upper face of the silicon substrate 10.

Then, a conductive film 24, for example, a polysilicon film is formed on the gate insulating film 23, Phosphorus is introduced as an impurity into the polysilicon film. The conductive film 24 is formed so as to embed the groove 21.

After that, as shown in FIGS. 9A and 9B, for example, a titanium nitride film is stacked on the conductive film 24 as a barrier metal film 25. Then, for example, a tungsten (W) film is formed therefrom as a low-resistance metal film 26.

Then, as shown in FIGS. 10A and 10B, for example, a SiN film is formed on the low-resistance metal film 26 as a film serving as a hard mask 27, and after that, patterning is performed by a photolithography method or the like and the hard mask 27 is formed. In the hard mask 27, a plurality of openings 28 are formed which extend in a direction in which the groove 21 extends within the surface of the silicon substrate 10 and which are aligned along the direction in which the groove 13 extends. The openings 28 are formed in an area directly above a region between the groove 21 and the groove 21.

Then, as shown in FIG. 11A, RIE is performed by using the hard mask 27 as a mask, and thus the low-resistance metal film 26, the barrier metal film 25 and the conductive film 24 are selectively removed. Because of this, on the portion covered by the hard mask 27, a gate electrode 29 made up of the low-resistance metal film 26, the barrier metal film 25 and the conductive film 24 is formed. A portion of the conductive film 24 that is embedded within the groove 21 is referred to as a lower conductive film 24a, and a portion on the upper face of the silicon substrate 10 other than the lower conductive film 24a is referred to an upper conductive film 24b.

In addition, a stacked body made up of the upper conductive film 24b, the barrier metal film 25, the low-resistance metal film 26 and the hard mask 27 is referred to as a stacked body 30.

Next, as shown in FIG. 11B, wet etching is performed by using the hard mask 27 as a mask, and the gate insulating film 23 is selectively removed.

After that, as shown in FIG. 12A, an extension side wall 31 is formed on the side face of the stacked body 30. After a silicon nitride film is formed on the silicon substrate 10, the extension side wall 31 is formed by removing a portion of the stacked body 30 other than the side face.

Then, as shown in FIG. 12B, phosphorus is ion-implanted into the silicon substrate 10 by using the stacked body 30 and the extension side wall 31 as a mask. Because of this, an extension region 32 is formed in a region of the silicon substrate 10 that is not covered by the stacked body 30 and the extension side wall 31.

Next, as shown in FIG. 13A, a source/drain side wall 33 is formed on the side wall of the stacked body 30. After a silicon nitride film is formed on the silicon substrate 10, the source/drain side wall 33 is formed by removing a portion of the stacked body 30 other than the side wall.

Then, as shown in FIG. 13B, phosphorus is ion-implanted into the silicon substrate 10 using the stacked body 30, the extension side wall 31 and the source/drain side wall 33 as a mask. Because of this, a source/drain region 34 is formed in a region of the silicon substrate 10 that is not covered by the stacked body 30, the extension side wall 31 and the source/drain side wall 33. Phosphorus is implanted into the source/drain region 34 at a concentration higher than the concentration implanted into the extension region 32. In addition, phosphorus is implanted into the source/drain region 34 deeper than being implanted into the extension region 32.

Then, as shown in FIG. 14, an interlayer insulating film 35 is deposited on the silicon substrate 10, and after that, a contact hole 36 that reaches the source/drain region 34 is formed in the interlayer insulating film 35. A contact hole 37 is formed by embedding a conductive member in the contact hole 36.

In this way, the nonvolatile semiconductor memory cell 1 is completed.

Next, the effects of the invention will be described.

In the embodiment, the groove 21 in which a part of the gate electrode 29 of the RCAT is embedded is formed by RIE, and then the inhibition layer is removed by performing the plasma processing in the gas that contains fluorine or a fluoride. Because of this, by hydrogen thermal processing performed after the plasma processing, the movement of silicon atoms in the inner face of the groove 21 is not inhibited. Therefore, it is possible to repair roughness in the inner face of the groove 21 caused by RIE.

Furthermore, as shown in FIG. 15, for example, when a plurality of RCATs that are collected together form a cell region 51, the strength of impact of ions and the method of adherence of the reaction product differ between a case in which a groove 21a is formed in the center of the cell region 51 and a case in which a groove 21b is formed at an end of the cell region 51. Moreover, the strength of impact of ions and the method of adherence of the reaction product differ between a case in which the 21a is formed in the cell region 51 and a case in which a groove 21c is formed away from the cell region 51. In this way, the formed inhibition layer differs depending on the position in which the groove 21 is formed the arrangement density. However, since, in the embodiment, the inhibition layer is removed, in any of the grooves 21, the silicon atoms evenly move, and thus the roughness in the inner face of the groove 21 is repaired. Therefore, it is possible to evenly shape the groove 21. Since the groove 21 is evenly shaped, no variation in the electrical characteristics of the RCAT is generated. Hence, it is possible to manufacture the RCAT having a satisfactory electrical characteristics.

In the plasma processing, the gas that contains fluorine or a fluoride is unlikely to form a deposition of the reaction product. Thus, it is possible to remove the inhibition layer without newly forming a deposition layer of the reaction product.

When the plasma processing is performed, the bias voltage Vdc that is applied to the silicon substrate 10 is set so as to be not more than 100 V. When the bias voltage Vdc is set so as to be not more than 100 V, it is possible to reduce the impact of ions on the silicon substrate 10. Therefore, it is possible to remove the inhibition layer without newly forming an inhibition layer by the impact of ions.

### A Modification of the First Embodiment

Next, a modification of the first embodiment will be described.

FIG. 16 is a cross-sectional view illustrating grooves in a method for manufacturing a semiconductor device according to a modification of the first embodiment.

In the modification, the bottom portion of the groove 21 has a shape in which a convex portion 42 that becomes thinner as it extends downward is formed. The groove 21a, the groove 21b and the groove 21c have the same shape as the groove 21. Even in this case, since the groove 21 is evenly shaped, it is possible to manufacture the RCAT having favorable electrical characteristics. The configuration and effects of the modification other than what has been described above are the same as in the first embodiment described previously.

### A Comparative Example of the First Embodiment

Next, a comparative example of the first embodiment will be described.

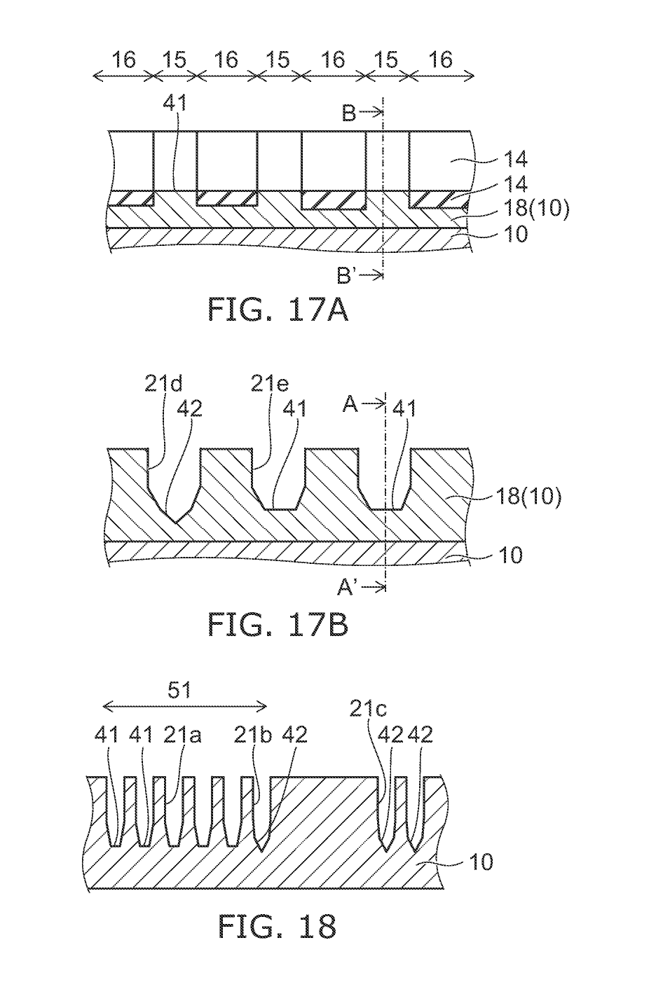

FIGS. 17A and 17B are process cross-sectional views illustrating a method for manufacturing a semiconductor device according to the comparative example of the first embodiment;

FIG. 17A is a cross-sectional view taken along line A-A′ shown in FIG. 17B; FIG. 17B is a cross-sectional view taken along line B-B′ shown in FIG. 17A.

FIG. 18 is a cross-sectional view illustrating grooves in the method for manufacturing the semiconductor device according to the comparative example of the first embodiment.

The processes shown in FIGS. 1A to 1C, 2A to 2C, 3A and 3B, 4A and 4B, 5A to 5C and 6A to 6C in the first embodiment described previously are first performed. The description of these processes will be omitted.

Then, as shown in FIGS. 17A and 17B, in the comparative example, after the RIE is performed, the silicon substrate 10 is subjected to thermal processing in hydrogen gas without being subjected to the plasma processing by using the gas that contains fluorine or a fluoride.

In the comparative example, after the groove 21 is formed by the RIE, the hydrogen thermal processing is performed without the plasma processing by using the gas that contains fluorine or a fluoride being performed. Therefore, in the hydrogen thermal processing, the inhibition layer inhibits the movement of silicon in the inner face of the groove 21. Depending on the arrangement density and the position of the groove 21, the inhibition layer differs in its size and shape and the method of adherence. Therefore, the method of inhibiting the movement of silicon atoms differs depending on the arrangement density and the position of the formed groove 21. Consequently, even when the cross-sectional shape of the groove 21 remains the same after the RIE, it differs depending on the arrangement density and the position of the formed groove 21, after the hydrogen thermal processing.

For example, as shown in FIG. 17B, in a groove 21d, the convex portion 42 that becomes thinner as it extends downward is formed in the bottom portion of the groove 21d whereas, in a groove 21e, a flat face 41 is formed in the bottom portion of the groove 21e.

Then, the processes shown in FIGS. 8A and 8B, 9A and 98, 10A and 10B, 11A and 118, 12A and 12B, 13A and 13B and 14 in the first embodiment described previously are performed. The description of these processes will be omitted.

In this way, the semiconductor device according to the comparative example is manufactured.

As an example in which, as shown in FIG. 18, the cross-sectional shape of the groove 21 differs depending on the arrangement density and the position of the formed groove 21, the following example is included. Specifically, when a plurality of RCATs that are collected together form the cell region 51, the groove 21a formed in the center of the cell region 51 and the groove 21b formed in the end of the cell region 51 are taken as the example. Between the groove 21a and the groove 21b, the strength of the impact of ions and the degree and the state of adherence of the reaction product differ. Consequently, the conditions in which the inhibition layer inhibits the movement of silicon atoms differ. Therefore, the cross-sectional shape of the groove 21a and the cross-sectional shape of the groove 21b differ from each other. For example, the bottom portion of the groove 21a becomes the flat face 41 whereas the bottom portion of the groove 21b becomes the convex portion 42 that is convex downward.

Furthermore, as another case in which the cross-sectional shape of the groove 21 differs, the groove 21a formed in the center of the cell region 51 and the groove 21c formed away from the cell region 51 are included. Between the groove 21a and the groove 21c, the strength of the impact of ions and the degree and the state of adherence of the reaction product differ. Consequently, the conditions in which the inhibition layer inhibits the movement of silicon atoms also differ. Therefore, the cross-sectional shape of the groove 21a and the cross-sectional shape of the groove 21c differ from each other. For example, the bottom portion of the groove 21a becomes the flat face 41 whereas the bottom portion of the groove 21c becomes the convex portion 42 that is convex downward.

In this way, the difference in the shape of the groove 21 causes variations in the electrical characteristics of the RCAT.

### Second Embodiment

Next, the second embodiment will be described.

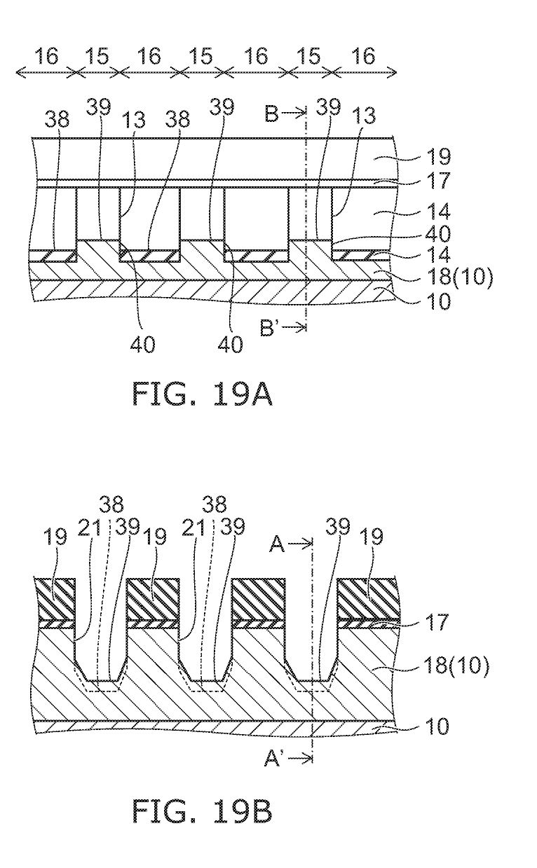

FIGS. 19A and 19B are process cross-sectional views illustrating a method for manufacturing a semiconductor device according to the second embodiment, FIG. 19A is a cross-sectional view taken along line A-A′ shown in FIG. 19B, and FIG. 19B is a cross-sectional view taken along line B-B′ shown in FIG. 19A.

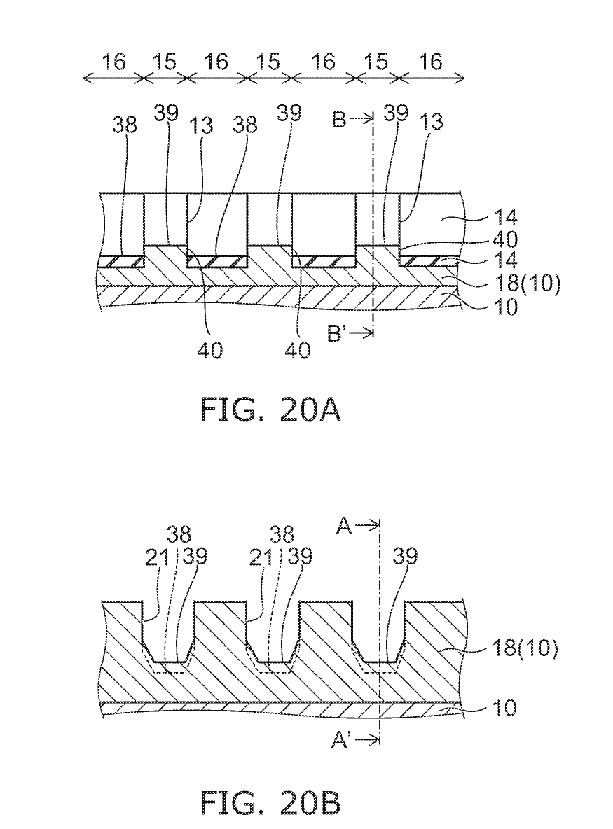

FIGS. 20A and 20B are process cross-sectional views illustrating the method for manufacturing the semiconductor device according to the second embodiment, FIG. 20A is a cross-sectional view taken along line A-A′ shown in FIG. 20B, and FIG. 20B is a cross-sectional view taken along line B-B′ shown in FIG. 20A.

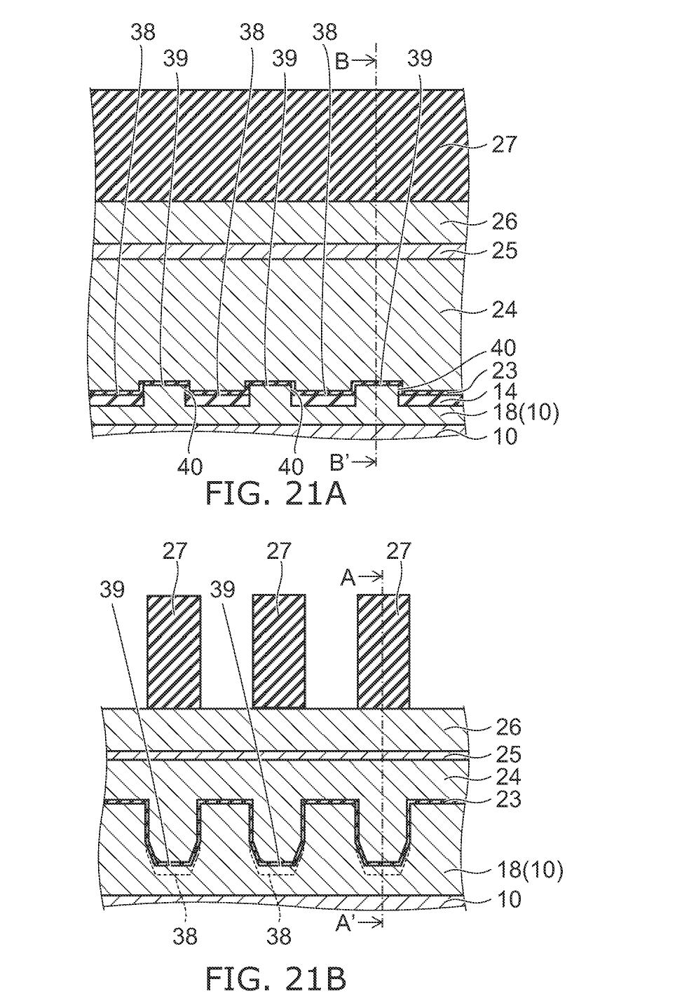

FIGS. 21A and 21B are process cross-sectional views illustrating the method for manufacturing the semiconductor device according to the second embodiment, FIG. 21A is a cross-sectional view taken along line A-A′ shown in FIG. 21B, and FIG. 21B is a cross-sectional view taken along line B-B′ shown in FIG. 21A.

The embodiment is an example in which a RCAT having a saddle fin formed is manufactured.

The processes shown in FIGS. 1A to 1C, 2A to 2C, 3A and 3B, 4A and 4B and 5A to 5C in the first embodiment described previously are first performed. The description of these processes will be omitted.

Then, as shown in FIGS. 19A and 19B, RIE is performed using the hard mask 19 as a mask, and the silicon oxide film 17 is selectively removed. Furthermore, the silicon substrate 10 in the active region 15 and the silicon oxide film 14 in the STI region 16 are selectively removed. Because of this, the grooves 21 are formed in the silicon substrate 10. In a method for manufacturing the semiconductor device of the embodiment, before the plasma processing is performed, the silicon oxide film 14 on the bottom face of the groove 21 is removed. Therefore, the bottom face 38 of the groove 21 in the STI region 16 is located lower than the bottom face 39 of the groove 21 in the active region 15. In addition, a step is formed between the bottom face 38 and the bottom face 39. The side face 40 of the groove 13 is exposed from the step.

After that the hard mask 19 is removed by heated phosphoric add or the like. Furthermore, the silicon oxide film 17 that remains directly below the hard mask 19 is removed by diluted hydrofluoric add.

Then, as shown in FIGS. 20A and 20B, the silicon substrate 10 in which the grooves 21 are formed is plasma-processed in the gas that contains fluorine or a fluoride. After that, thermal processing is performed in hydrogen gas.

Then, as shown in FIGS. 21A and 21B, the gate insulating film 23 is formed on the inner face of the groove 21 and on the upper face of the silicon substrate 10. The gate insulating film 23 is formed so as to cover the bottom face 38, the bottom face 39 and the side face 40.

Then, the conductive film 24 is formed on the gate insulating film 23. The conductive film 24 is formed so as to cover the gate insulating film 23 formed on the bottom face 38, the bottom face 39 and the side face 40 and so as to be embedded in the groove 21.

After that, the barrier metal film 25 is stacked on the conductive film 24. Then, the low-resistance metal film 26 is formed therefrom. On the low-resistance metal film 26, as a film serving as the hard mask 27, for example, after the formation of a SiN film, the hard mask 27 is formed by patterning with a photolithography method or the like.

Then, the processes shown in FIGS. 11A and 11B, 12A and 12B, 13A and 13B and 14 in the first embodiment described previously are performed. The description of these processes will be omitted.

In this way, the semiconductor device according to the second embodiment is manufactured.

Next, the effects of the embodiments will be described.

In a method for manufacturing the semiconductor device according to the embodiment, the side face 40 of the groove 13 is exposed from the bottom face of the groove 21. Because of this, on the bottom face of the groove 21 in the active region 15, a so-called saddle fin is formed. In addition, the gate insulating film 23 is also formed on the side face 40 of the groove 13. That is, a region of the silicon substrate 10 adjacent to three surfaces that are the bottom face 39 covered by the gate insulating film 23 in the active region 15 and the two side faces 40 serves as the channel of the RCAT. Therefore, it is possible to increase the area of the channel and the amount of current flowing through the channel. Furthermore, since the channel is surrounded by the gate electrode 29 in the three directions of the three surfaces, it is possible to accurately control the potential of the channel through the use of the gate electrode 29.

In order for the side face 40 of the groove 13 to be exposed, the silicon oxide film 14 on the bottom face of the groove 21 is removed. In this case, etching conditions under which the silicon substrate 10 in the active region 15 is not removed are used. Since there are cases in which the energy of the ions is increased under such conditions, a large number of inhibition layers may be formed on the inner face of the groove 21.

Since, in the embodiment, the inhibition layers is removed by the plasma processing before the hydrogen thermal processing, even if the energy of the ions in the etching gas at the time of the formation of the saddle fin is increased, it is possible to make uniform the shape of the groove 21.

Therefore, it is possible to manufacture the semiconductor device having favorable electrical characteristics. The effects of the embodiment other those described above are the same in the first embodiment described previously.

### Third Embodiment

Next, the third embodiment will be described.

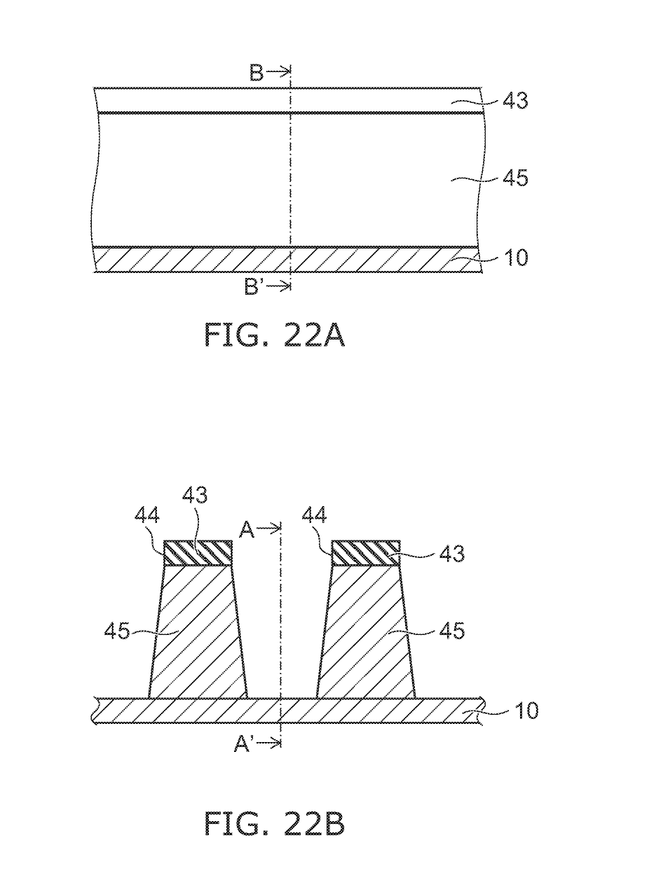

FIGS. 22A and 22B are process cross-sectional views illustrating a method for manufacturing a semiconductor device according to the third embodiment, FIG. 22A is a cross-sectional view taken along line A-A′ shown in FIG. 22B, and FIG. 22B is a cross-sectional view taken along line B-B′ shown in FIG. 22A.

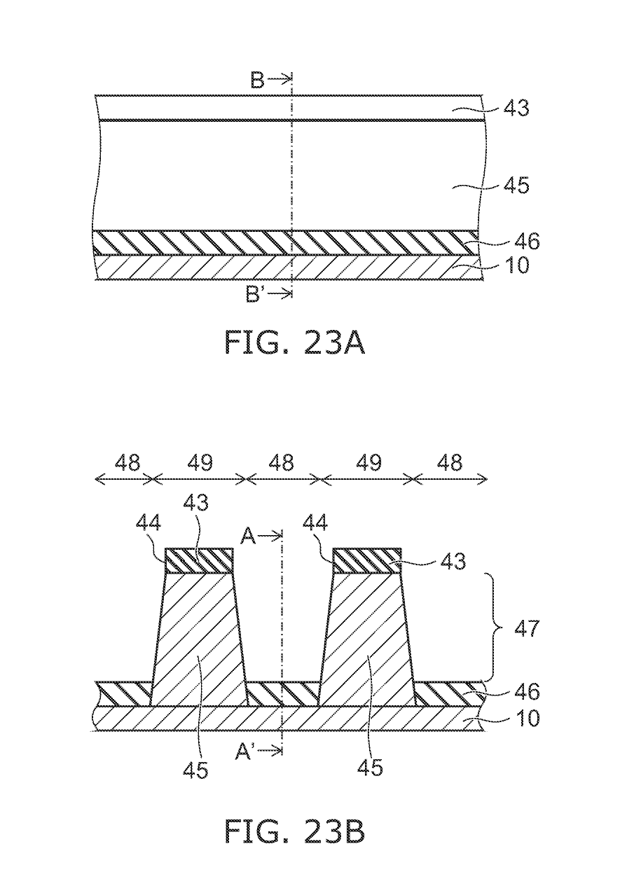

FIGS. 23A and 23B are process cross-sectional views illustrating the method for manufacturing the semiconductor device according to the third embodiment, FIG. 23A is a cross-sectional view taken along line A-A′ shown in FIG. 23B, and FIG. 23B is a cross-sectional view taken along line B-B′ shown in FIG. 23A.

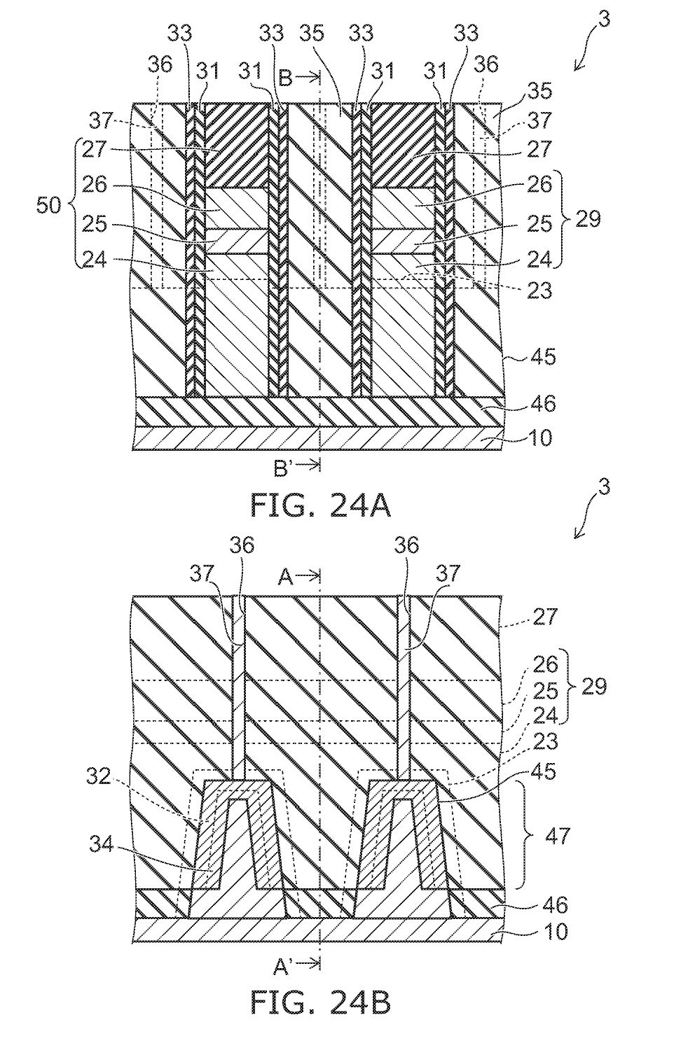

FIGS. 24A and 24B are process cross-sectional views Illustrating the method for manufacturing the semiconductor device according to the third embodiment, FIG. 24A is a cross-sectional view taken along line A-A′ shown in FIG. 24B, and FIG. 24B is a cross-sectional view taken along line B-B′ shown in FIG. 24A.

The embodiment is an example in which a fin transistor is manufactured.

As shown in FIGS. 22A and 22B, the silicon substrate 10 is first prepared. Then, a hard mask 43 is formed on the silicon substrate 10. The hard mask 43 extends in one direction within the face of the silicon substrate 10, and forms a plurality of openings 44 aligned in a direction perpendicular to the one direction. After that, RIE is performed by using the hard mask 43 as a mask, and thereby forms columnar bodies 45 in an upper face portion of the silicon substrate 10.

Next, as shown in FIGS. 23A and 23B, the portion on the silicon substrate 10 which is covered by the hard mask 43 and which includes the columnar bodies 45 is covered with a silicon oxide film 46. Then, the silicon oxide film 46 is polished by the CMP method until the surface of the hard mask 43 appears.

Then, RIE is performed on the silicon oxide film 46 using the hard mask 43 as a mask, and thus the upper face of the silicon oxide film 46 is lowered back. The portion of the columnar body 45 on the upper face of the silicon oxide film 46 is referred to as a fin 47. As viewed from above, a region in which the silicon oxide film 46 remains on the silicon substrate 10 is referred to as an STI region 48. A region in which the fin sandwiched between the STI regions 48 is present is referred to as an active region 49. After that, the hard mask 43 is removed.

Then, the silicon substrate 10 on which the fins 47 are formed is subjected to the plasma processing by using the gas that contains fluorine or a fluoride. After that, thermal processing is performed in hydrogen gas.

Then, as shown in FIGS. 24A and 24B, for example, a silicon oxide film is formed on the upper face and the side face of the fin 47.

After that, the conductive film 24 is formed on the gate insulating film 23. The conductive film 24 is formed such that it covers the fins 47 and is located so as to be not less than the height of the fins 47.

Then, the barrier metal film 25 is formed on the conductive film 24. Then, the low-resistance metal film 26 is formed therefrom.

The hard mask 27 is formed on the low-resistance metal film 26. The hard mask 27 is formed by forming, for example, a silicon nitride film on the low-resistance metal film 21 and after that, by performing patterning through the use of a lithography method. The hard mask 27 is formed to be perpendicular to the direction in which the fin 47 extends.

Then, RIE is performed by using the hard mask 27 as a mask, and thus the low-resistance metal film 26, the barrier metal film 25, the conductive film 24 and the gate insulating film 23 are selectively removed. In this way, on the portion covered by the hard mask 27, the gate electrode 29 made up of the low-resistance metal film 26, the barrier metal film 25, and the conductive film 24 is formed. A stacked body made up of the hard mask 27 and the gate electrode 29 is referred to as a stacked body 50.

In contrast, on the surface of the portion that is not covered by a hard mask 22, the upper face and the side face of the fin 47 appear.

The extension side wall 31 is formed on the side face of the stacked body 50. Phosphorus is ion-implanted into the fin 47 by using the stacked body 50 and the extension side wall 31 as a mask. Therefore, the extension region 32 is formed in a region of the fin 47 that is not covered by the stacked body 50 and the extension side wall 31.

Furthermore, the source/drain side wall 33 is formed on the side wall of the stacked body 50. Then, phosphorus is ion-implanted into the fin 47 by using the stacked body 50, the extension side wall 31 and the source/drain side wall 33 as a mask. Because of this, the source/drain region 34 is formed in a region of the fin 47 that is not covered by the stacked body 50, the extension side wall 31 and the source/drain side wall 33.

Then, after the interlayer insulating film 35 is deposited on the silicon substrate 10, the contact hole 36 that reaches the source/drain region 34 is formed on the interlayer insulating film 35. The contact 37 is formed by embedding a conductive member within the contact hole 36.

In this way, a semiconductor device 3 is manufactured,

Next, the benefits of the embodiment will be described.

In the embodiment, after the fin 47 is formed by RIE, the plasma processing is performed in the gas that contains fluorine or a fluoride, and thus the inhibition layer is removed. Since silicon atoms uniformly move in all the fins 47 in this way, it is possible to make uniform the shape of the fins 47. Therefore, since no variation is generated in the electrical characteristics of the fin transistor, it is possible to manufacture the fin transistor having favorable electrical characteristics.

In order for the fin 47 to be formed, the silicon oxide film 46 in the STI region 48 is removed. In this case, etching conditions under which the fin 47 is not removed are used. Since the energy of the ions is likely to be increased under such etching conditions, a large number of inhibition layers may be formed on the surface of the fin 47.

Since, in the embodiment, before the hydrogen thermal processing, the plasma processing is performed to remove the inhibition layers, even if the energy of the ions in the etching gas for removing the silicon oxide film 46 is increased, it is possible to make uniform the shape of the fin 47. Therefore, it is possible to manufacture the semiconductor device having favorable electrical characteristics. The effects of the embodiment other than those described above are the same in the first embodiment described previously.

According to the embodiments described above, it is possible to provide the semiconductor devices having favorable electrical characteristics.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor device, comprising:
forming, on an upper face of a silicon substrate, a plurality of concave portions extending in a first direction,
performing, in a gas that contains fluorine or a fluoride, plasma processing on the silicon substrate in which the concave portions are formed;
performing, in a gas that contains hydrogen, thermal processing on the silicon substrate after completion of performing the plasma processing;
forming an insulating film on an inner face of the concave portions after completion of performing the thermal processing; and
forming a conductive film on the insulating film.

2. The method according to claim 1, further comprising:
forming, on the upper face of the silicon substrate, a plurality of grooves extending a second direction intersecting with the first direction, before forming the concave portions;
forming an element isolation region by embedding an insulating member within the grooves; and
forming, on the silicon substrate in which the element isolation region is formed, a hard mask where a plurality of openings extending in the first direction are formed, wherein
forming the concave portions is performed by reactive on etching through the use of the hard mask as a mask.

3. The method according to claim 2, further comprising:
removing the insulating member in the concave portions before performing the plasma processing to thereby expose side faces of the grooves in the concave portions.

4. The method according to claim 1, wherein, in performing the plasma processing, the gas that contains fluorine or a fluoride is a gas selected from a group consisting of a single gas of fluorine, a single gas of nitrogen trifluoride and a single gas of sulphur hexafluoride.

5. The method according to claim 1, wherein, in performing the plasma processing, a bias voltage applied to the silicon substrate is set to be not more than 100 V.

6. The method according to claim 1, wherein forming the concave portions and performing the plasma processing are performed within a same chamber.

7. The method according to claim 2, wherein, in the reactive on etching, a CF₄ gas is used as an etching gas.

8. The method according to claim 2, wherein, in forming the concave portions, the silicon substrate and the element isolation region are processed simultaneously.

9. The method according to claim 2, wherein bottom faces of the concave portions in the silicon substrate and the element isolation region are formed into a flat face parallel to the upper face of the silicon substrate.

10. The method according to claim 1, wherein, in performing the plasma processing, the gas that contains fluorine or a fluoride contains at least one gas selected from a group consisting of a fluorine gas, a nitrogen trifluoride gas and a sulphur hexafluoride gas.

11. The method according to claim 1, wherein, in forming the insulating film, the insulting film is a silicon oxide film, and, in forming the conductive film, the conductive film is a polysilicon film, and the polysilicon film is formed so as to embed the concave portions.

12. The method according to claim 1, further comprising:
removing a portion directly above a region between the concave portions in the conductive film to thereby form a gate electrode containing the conductive film.

13. The method according to claim 12, further comprising:
forming source/drain region in a region of the silicon substrate which is not covered by the gate electrode, by performing on implantation on the silicon substrate through the use of the gate electrode as a mask.

14. The method according to claim 2, wherein bottom portions of the concave portions in the silicon substrate and the element isolation region are formed such that the bottom portions become thinner as the bottom portions extend downward.

15. The method according to claim 3, wherein, in exposing the side faces of the grooves, bottom faces of the concave portions in the element isolation region are located lower than bottom faces of the concave portions in the silicon substrate.

16. A method for manufacturing a semiconductor device, comprising:
forming, on an upper layer of a silicon substrate, a plurality of columnar bodies extending in a first direction;
performing, in a gas that contains fluorine or a fluoride, plasma processing on the silicon substrate in which the columnar bodies are formed;
performing, in a gas that contains hydrogen, thermal processing on the silicon substrate after completion of performing the plasma processing;
forming an insulating film on an upper face and a side face of the columnar bodies after completion of performing the thermal processing; and
forming a conductive film on the insulating film.

17. The method according to claim 16, further comprising, before performing the plasma processing:
forming an insulating film between the columnar bodies; and
lowering an upper face of the insulating film back below an upper face of the columnar bodies.

18. The method according to claim 16, wherein, in performing the plasma processing, the gas that contains fluorine or a fluoride is a gas selected from a group consisting of a single gas of fluorine, a single gas of nitrogen trifluoride and a single gas of sulphur hexafluoride.

19. The method according to claim 16, wherein, in performing the plasma processing, a bias voltage applied to the silicon substrate is set to be not more than 100 V.

20. The method according to claim 16, further comprising:
forming, on the conductive film, a hard mask in which a plurality of openings extending in a second direction intersecting with the first direction are formed; and
etching the conductive film through the use of the hard mask as a mask to form a gate electrode including the conductive film extending in the first direction.
